(19) United States
(12) Patent Application Publication
(10) Pub. No.: US 2019/0109243 A1
(43) Pub. Date: Apr. 11, 2019

(54) BACK-GATE CONTROLLED VARACTOR

(71) Applicant: GLOBALFOUNDRIES INC., Grand Cayman (KY)

(72) Inventor: Chi ZHANG, Allen, TX (US)

(21) Appl. No.: 15/727,040

(22) Filed: Oct. 6, 2017

(51) Int. Cl. H01L 29/93; H01L 27/02; H03B 5/12; H03L 7/06; H01L 29/94

(52) U.S. Cl. CPC H01L 29/93; H01L 27/0203; H01L 29/94; H03L 7/06; H03B 5/1212

(57) ABSTRACT

The present disclosure relates to semiconductor structures and, more particularly, to a back-gate controlled varactor and methods of use and manufacture. The varactor includes: a plurality of transistors arranged in parallel; a voltage controlled node coupled to back-gates of the plurality of transistors; and a biasing voltage node coupled to the source and drain of the plurality of transistors.

### FIELD OF THE INVENTION

The present disclosure relates to semiconductor structures and, more particularly, to a back-gate controlled varactor and methods of use and manufacture.

### BACKGROUND

Varactors are used in voltage-controlled oscillators (VCO) for frequency tuning, where the VCO frequency is tuned by a control voltage. Voltage-controlled oscillators have many applications such as frequency modulation for FM transmitters and phase-locked loops. Phase-locked loops can be used for frequency synthesizers that tune, for example, cellular telephones or other wireless devices.

Diode based varactors are operated in a reverse-biased state, where the amount of reverse bias controls the thickness of the depletion zone and therefore the varactor's junction capacitance. The capacitance is inversely proportional to the square root of applied voltage. Conventional MOS based varactors are operated in either accumulation mode or inversion mode. The gate capacitance is a function of the relative gate bias. That is, varactors show capacitance as function of control voltage (C-V curve). By way of example, an LC (inductor/capacitor)-tank based VCO has output frequency as function of the varactor capacitance.

Conventional varactors exhibit high gain, noise, AC coupling and limited control voltage range. More specifically, a conventional Metal-Oxide-Semiconductor Capacitor (MOSCAP) based varactor uses Vgs voltage as the control voltage, which has a C-V curve with a steep slope. The capacitance value is sensitive to control voltage level, with the VCO gain (Kv) being high. Additionally, VCO phase noise is sensitive to the control voltage noise due to high gain. Moreover, to bias the MOSCAP based varactor, AC coupling capacitors and DC coupling resistors are required on the gates of the MOSCAP device, which increases the design complexity, area, and parasitic capacitance. The resistors also contribute to the noise. Lastly, the MOSCAP based varactor has small control voltage range which is limited by the reliability constrain on the gates.

### SUMMARY

In an aspect of the disclosure, a varactor comprises: a plurality of transistors arranged in parallel; a voltage controlled node coupled to back-gates of the plurality of transistors; and a biasing voltage node coupled to the source and drain of the plurality of transistors.

In an aspect of the disclosure, a varactor comprises: a voltage controlled node directly coupled to back-gates of a pair of transistors to achieve gate capacitance tuning; and a biasing voltage node directly coupled to the source and drain of the transistors. The transistors are back-gate controlled by a voltage applied at the voltage controlled node.

In an aspect of the disclosure, a method of using a varactor comprises applying threshold voltage dependence on a back-gate bias of the varactor to achieve gate capacitance tuning.

### BRIEF DESCRIPTION OF THE DRAWINGS

The present disclosure is described in the detailed description which follows, in reference to the noted plurality of drawings by way of non-limiting examples of exemplary embodiments of the present disclosure.

FIG. 1 shows a back-gate controlled varactor in accordance with aspects of the present disclosure.

FIG. 2 shows a VCO directly coupled to the back-gate controlled varactor in accordance with aspects of the present disclosure.

FIG. 3 shows a VCO directly coupled to the back-gate controlled varactor in accordance with aspects of the present disclosure.

FIG. 4 shows a C-V curve which includes a simulation of the back-gate controlled varactor in accordance with aspects of the present disclosure.

FIG. 5 shows a frequency tuning and Kv curve of the back-gate controlled varactor in accordance with aspects of the present disclosure.

### DETAILED DESCRIPTION

The present disclosure relates to semiconductor structures and, more particularly, to a back-gate controlled varactor and methods of use and methods of manufacture. More specifically, the present disclosure provides a varactor which uses a back-gate as the voltage control (VCTRL) node. Advantageously, the back-gate controlled varactor exhibits low noise, low gain, capability of direct coupling to a VCO and wide control voltage range, compared to conventional varactors.

In embodiments, the back-gate controlled varactor described herein uses threshold voltage dependence on the back-gate bias to achieve gate capacitance tuning. In addition, the front-gates (transistors) of the varactor can be directly coupled to an LC-tank of a VCO (without coupling resistors or coupling capacitors), where the VCO uses the back-gate controlled varactor. For example, the back-gate controlled varactor can be used with a 60 GHz VCO which is suitable for 5G 28 GHz band local oscillator (LO) generation. In operation, the VCO inductor center tap voltage provides the varactor front-gates DC bias. In addition, in operation, the varactor C-V curve can be adjusted by a bias voltage (VS).

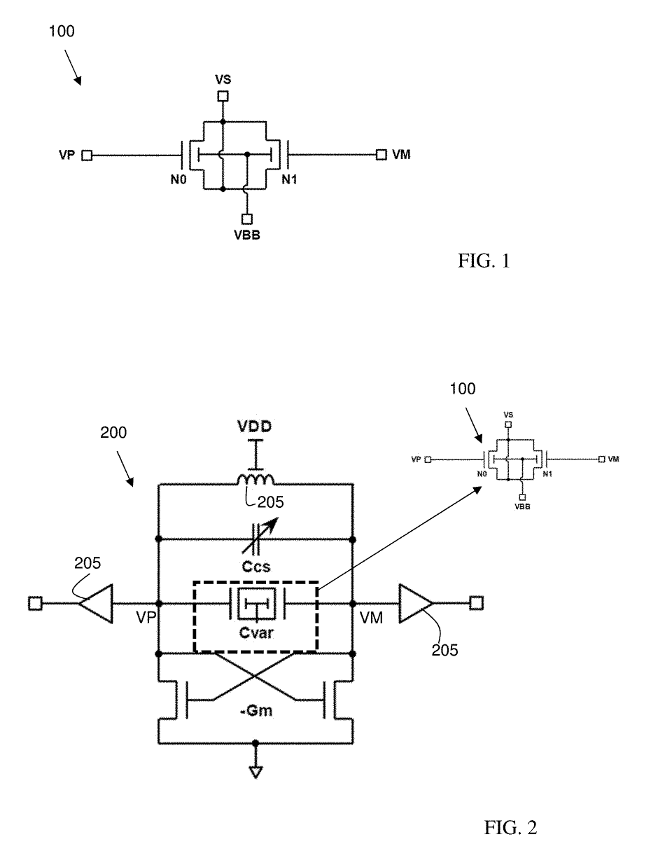

FIG. 1 shows a back-gate controlled varactor in accordance with aspects of the present disclosure. In embodiments, the back-gate controlled varactor 100 includes two transistors N0, N1 arranged in parallel, with the front-gates of the transistors N0, N1 directly coupled to an LC-tank positive (VP) node and negative (VM) node, respectively. In embodiments, the transistors N0, N1 are NMOS fully depleted SOI (FDSOI) devices or PMOS fully depleted SOI (FDSOI) devices with source/drain nodes shorted (electrically coupled) to node VS. In operation, the transistors N0, N1 are biased in a sub-threshold region by setting a proper VS potential.

As further shown in FIG. 1, the back-gates of the transistors N0, N1 are shorted (e.g., electrically coupled) together at VBB node. As should be understood by those of skill in the art, the VBB node is a voltage controlled node (e.g., VCTRL). In this way, the transistors N0, N1 are back-gate controlled by a voltage applied at the VBB node. In embodiments, the back-gate controlled varactor 100 exhibits a wide control voltage range which is due to the back-gate having a very high breakdown voltage. For example, VBB voltage can be 0V to 3.0V or higher, without being limited by device reliability requirements. This is compared to a conventional varactor which has a voltage range of about 0V to 0.8V.

Capacitance tuning of the back-gate controlled varactor 100 is achieved by changing the threshold voltage of the transistors N0, N1 through adjusting the back-gate bias, which creates a varactor C-VBB curve. In the back-gate controlled varactor 100 described herein, capacitance is less sensitive to the back-gate voltage VBB compared to a conventional front-gate voltage controlled varactor. This, in turn, allows the back-gate controlled varactor 100 to exhibit low gain and higher range (compared to conventional front gate biased varactors). The varactor gain can also be adjusted by using different VS bias.

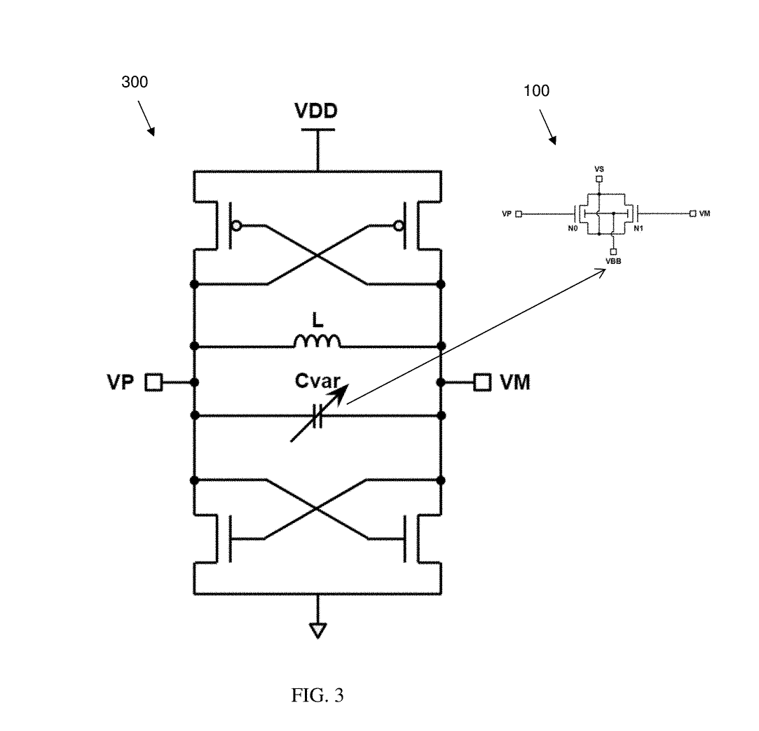

Still referring to FIG. 1, the front gates of the transistors N0, N1 are DC biased at nodes VP/VM by an applied DC voltage. Depending on the VCO type, e.g., NMOS cross-coupled VCO (FIG. 2) or a CMOS cross-coupled VCO (FIG. 3), the front gates of the varactor 100 can be biased differently. For example, VDD/2 is applied for a CMOS cross-coupled VCO (where the sources of the PMOS are biased at VDD, and VP and VM are approximately VDD/2); whereas, a center tap (CTAP) voltage is applied for a NMOS or PMOS only cross coupled VCO (VP=VM=VDD). The differential capacitance (VP to VM) is approximately half of the gate capacitance of the transistors N0 and N1.

Accordingly, by using the back-gate controlled varactor 100 it is now possible to provide low gain, low noise, direct coupling to a VCO and wide control voltage range. For example, the low gain is due to the varactor capacitance being less sensitive to the back-gate voltage. Low noise is due to the voltage line noise being suppressed due to low VCO gain. The varactor can be directly coupled to an LC tank of a VCO, since no AC coupling capacitors or DC coupling resistors are required. This saves considerable area, reduces parasitic capacitance, extends tuning range and achieves low noise. In addition, the back-gate controlled varactor exhibits a wide control voltage range due to the back-gate having a very high breakdown voltage.

FIG. 2 shows a VCO directly coupled to the back-gate controlled varactor in accordance with aspects of the present disclosure. In embodiments, the low gain varactor, e.g., back-gate controlled varactor 100, is especially important for a mm-wave VCO for better phase noise. In addition, direct coupling to the back-gate controlled varactor 100 is especially important for a mm-wave VCO to reduce parasitic capacitance to achieve very high frequency and wide tuning range. In embodiments, the back-gate controlled varactor 100 can be used in different types of VCOs, e.g., NMOS cross-coupled VCO (FIG. 2) or a CMOS cross-coupled VCO (FIG. 3).

More specifically and still referring to FIG. 2, the VCO 200 is directly coupled to the back-gate controlled varactor 100, where VDD is the supply voltage of the VCO 200. In operation, VDD is used to bias the front-gates of the back-gate controlled varactor 100. More specifically, the voltage VDD supplied to the VCO 200 is provided through an inductor 210, prior to biasing the front-gates of the back-gate controlled varactor 100. Accordingly, the VCO inductor 210 (center tap) voltage provides a DC bias to the front-gates of the back-gate controlled varactor 100. As should be understood herein, the back-gate controlled varactor 100 can be directly coupled to the VCO 200 without the need for coupling capacitors or coupling resistors. The front-gates of the back-gate controlled varactor 100 are also directly coupled to the nodes VP and VM. The VCO 200 further includes buffers 205, in line with nodes VP and VM. That is, VP/VM are the nodes at buffer input 205.

FIG. 3 shows a CMOS cross-coupled VCO 300 directly coupled to the back-gate controlled varactor 100 in accordance with aspects of the present disclosure. In this implementation, the VCO 300 is directly coupled to the back-gate controlled varactor 100, where VDD is the supply voltage of the VCO 300. In operation, the front-gates of the back-gate controlled varactor 100 are biased at about VDD/2.

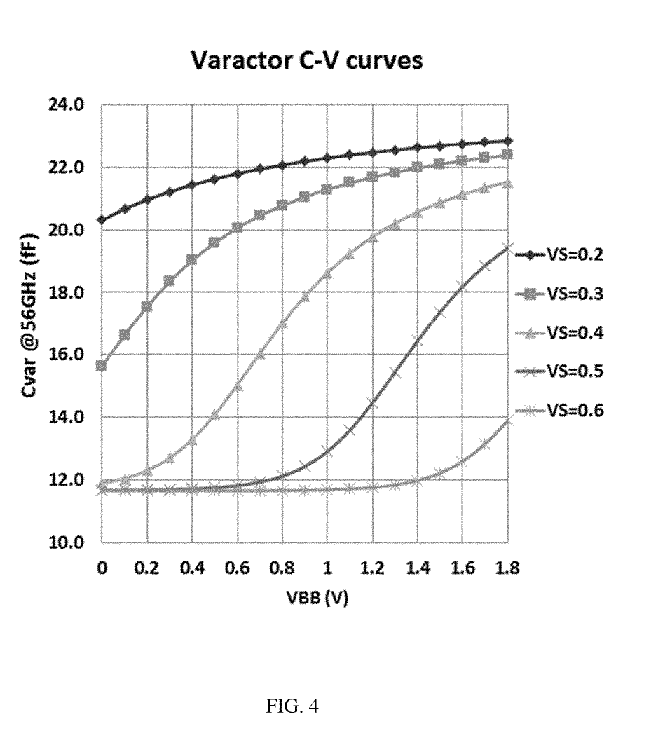

FIG. 4 shows a C-V curve which includes a simulation of the back-gate controlled varactor 100 in accordance with aspects of the present disclosure. In FIG. 4, the y-axis represents capacitance at 56 GHz and the x-axis represents voltage VBB. As shown in FIG. 3, when VS is fixed at 0.4 V and VBB sweeps between 0.8 V to 1.0 V, the capacitance changes by 1.5 fF. In addition, the C-V slope is 7.5 fF/V, noting that the gain is represented by the slope of the curve. This is compared to a conventional MOS varactor which has a capacitance change of 8.5 fF and a C-V slope of 42.5 fF/V when VBB is fixed at 0.9 V and VS sweeps between 0.3 V to 0.5 V. Accordingly, a VCO gain is about 5.7 times lower for the back-gate controlled varactor 100 compared to the conventional MOS varactor, assuming a same sized transistor being used for both varactors.

The graph of FIG. 4 further shows that VS can be set to different operating points to provide flexibility to the system. In addition, by fixing VBB and sweeping VS, the back-gate controlled varactor 100 described herein can also act similar to a conventional MOS varactor.

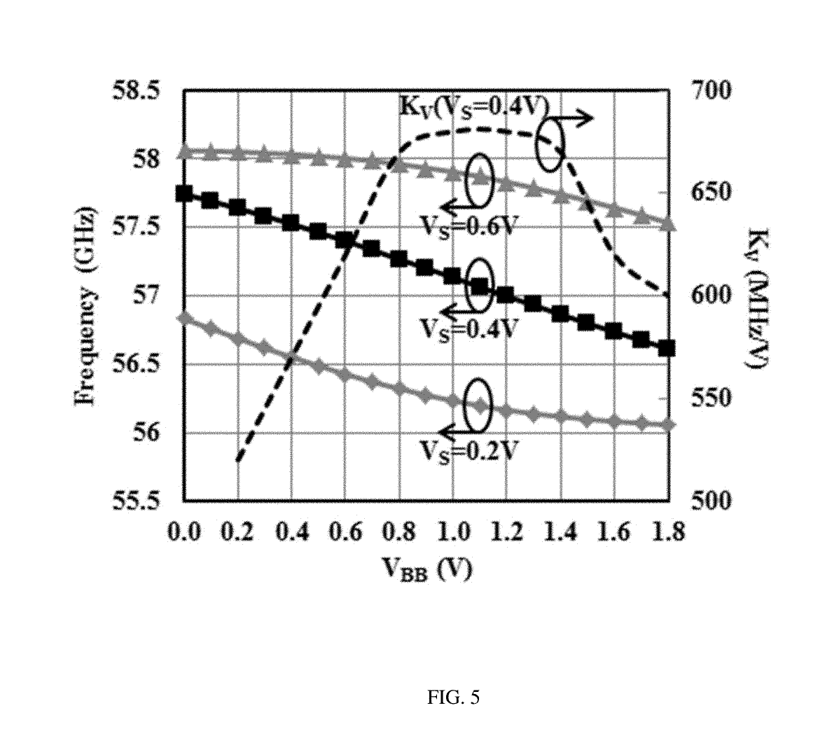

FIG. 5 shows a frequency tuning and Kv (gain) curve of the back-gate controlled varactor in accordance with aspects of the present disclosure. More specifically, FIG. 4 shows a measurement result of frequency tuning and Kv curve for a 57 GHZ VCO. In this graph, the y-axis represents frequency (GHz) and gain (Kv), whereas, the x-axis represents voltage VBB. The dashed line is representative of the performance of the back-gate controlled varactor in accordance with aspects of the present disclosure. For example, at a voltage of between 0.8 V and 1.0 V, the back-gate controlled varactor shows linear gain as represented by the flat portion of the curve, e.g., a gain of about 680 MHz/V.

The back-gate controlled varactor of the present disclosure can be manufactured in a number of ways using a number of different tools. In general, though, the methodologies and tools are used to form structures with dimensions in the micrometer and nanometer scale. The methodologies, i.e., technologies, employed to manufacture the back-gate controlled varactor of the present disclosure have been adopted from integrated circuit (IC) technology. For example, the structures are built on wafers and are realized in films of material patterned by photolithographic processes on the top of a wafer. In particular, the fabrication of the back-gate controlled varactor uses three basic building blocks: (i) deposition of thin films of material on a substrate, (ii) applying a patterned mask on top of the films by photolithographic imaging, and (iii) etching the films selectively to the mask.

The method(s) as described above is used in the fabrication of integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

1. A varactor, comprising:
a plurality of transistors arranged in parallel;
a voltage controlled node coupled to back-gates of the plurality of transistors; and
a biasing voltage node coupled to the source and drain of the plurality of transistors,
wherein front-gates of the transistors are directly coupled to an inductor/capacitor (LC)-tank positive (VP) node of a LC-tank of a voltage-controlled oscillator (VCO) and a LC-tank negative (VP) node of the LC-tank of the VCO.

2. The varactor of claim 1, wherein the plurality of transistors includes NMOS fully depleted SOI (FDSOI) devices or PMOS fully depleted SOI (FDSOI) devices.

3. The varactor of claim 2, wherein source/drain of the plurality of transistors are electrically coupled together by the biasing voltage node.

4. The varactor of claim 3, wherein the plurality of transistors are biased at a sub-threshold region by the biasing voltage node.

5. The varactor of claim 1, wherein the plurality of transistors are back-gate controlled by a voltage applied at the voltage controlled node.

6. The varactor of claim 1, wherein capacitance tuning of the varactor is achieved by changing a threshold voltage of the plurality of transistors through adjusting a back-gate bias of the plurality of transistors.

7. The varactor of claim 1, wherein the front-gates of the plurality of transistors are DC biased at the LC-tank positive (VP) node and the LC-tank negative (VM) node, respectively of an applied DC voltage.

8. (canceled)

9. The varactor of claim 1, wherein a VCO inductor center tap voltage provides a DC bias to the front-gates of the plurality of transistors.

10. The varactor of claim 9, wherein a gain of the VCO is adjusted by a biasing voltage applied by the biasing voltage node coupled to the source and drain of the plurality of transistors.

11. The varactor of claim 1, wherein a capacitance-voltage (C-V) curve is adjusted by the bias voltage node coupled to the source and drain of the plurality of transistors.

12. The varactor of claim 1, wherein a voltage of the voltage-controlled oscillator (VCO) is directly coupled to the back-gates of the plurality of transistors.

13. A varactor, comprising:
a voltage controlled node directly coupled to back-gates of a pair of transistors to achieve gate capacitance tuning; and
a biasing voltage node directly coupled to the source and drain of the transistors which biases the transistors in sub-threshold region by the biasing voltage node,
wherein the transistors are back-gate controlled by a voltage applied at the voltage controlled node, and
front-gates of the transistors are directly coupled to an inductor/capacitor (LC)-tank positive (VP) node of a LC-tank of a voltage-controlled oscillator (VCO) and a LC-tank negative (VP) node of the LC-tank of the VCO.

14. The varactor of claim 13, wherein source/drain of the transistors are electrically coupled together by the biasing voltage node.

15. The varactor of claim 13, wherein capacitance tuning of the varactor is achieved by changing a threshold voltage of the transistors through adjusting a back-gate bias of the transistors.

16. The varactor of claim 13, wherein the front-gates of the transistors are DC biased at the LC-tank positive (VP) node and the LC-tank negative (VM) node by an applied DC voltage.

17. The varactor of claim 16, wherein a voltage of the voltage-controlled oscillator (VCO) is directly coupled to the back-gates of the transistors such that a NMOS cross-coupled VCO inductor center tap voltage provides a DC bias (VDD) to the front-gates of the varactor.

18. The varactor of claim 16, wherein a voltage of the VCO is directly coupled to the back-gates of the transistors such that a CMOS cross-coupled VCO supply voltage provides a DC bias (VDD/2) to the front-gates of the varactor.

19. The varactor of claim 17, wherein a gain of the VCO is adjusted by a biasing voltage applied by the biasing voltage node coupled to the source and drain of the transistors and a C-V curve is adjusted by the bias voltage node directly coupled to the source and drain of the transistors.

20. A method of using a varactor comprising applying threshold voltage dependence on a back-gate bias of the varactor to achieve gate capacitance tuning and directly coupling front-gates of a plurality of transistors of the varactor to an inductor/capacitor (LC)-tank positive (VP) node of a LC-tank of a voltage-controlled oscillator (VCO) and a LC-tank negative (VP) node of the LC-tank of the VCO.

21. The varactor of claim 1, wherein the back-gates of the plurality of transistors have a high breakdown voltage in a range of 0 volts to 3.0 volts by adjusting a back-gate bias of the transistors.
